(19) United States
(12) Patent Application Publication
(10) Pub. No.: US 2024/0070332 A1
(43) Pub. Date: Feb. 29, 2024

(54) DIGITAL MATERIAL COLLABORATION PLATFORM

(71) Applicant: Siemens Aktiengesellschaft, Munich (DE)

(72) Inventors: Sonja Wolfrum, Erlangen (DE); Martin Kördel, Munich (DE); David Madeley, Louth (DE); Anna Matveeva, Leuven (BE)

(21) Appl. No.: 17/823,587

(22) Filed: Aug. 31, 2022

(51) Int. Cl. G06F 30/10

(52) U.S. Cl. CPC G06F 30/10

(57) ABSTRACT

A computing system may include a digital material collaboration engine configured to construct a digital material that is partially-defined based on input from a requestor entity of a digital material collaboration platform. The digital material may be for the manufacture of a physical product and may be partially-defined to include a physical material or product requirements for the physical product, but does not define process parameters of a manufacturing process to manufacture the physical product. The digital material collaboration engine may further be configured to receive, from provider entities of the digital material collaboration platform, proposed versions for the digital material that specify process parameters for the manufacturing process, and connect the requestor entity with a selected provider entity of the provider entities of the digital material collaboration platform based on a particular proposed version for the digital material provided by the selected provider entity.

### BACKGROUND

Computer systems can be used to create, use, and manage data for products and other items. Examples of computer systems include computer-aided design (CAD) systems (which may include computer-aided engineering (CAE) systems), visualization and manufacturing systems, product data management (PDM) systems, product lifecycle management (PLM) systems, and more. These systems may include components that facilitate the design and simulated testing of product structures and product manufacture.

### BRIEF DESCRIPTION OF THE DRAWINGS

Certain examples are described in the following detailed description and in reference to the drawings.

FIG. 1 shows an example of a client computing system that supports digital material collaboration platforms.

FIG. 2 shows an example generation and exchange of various versions of digital materials according to the present disclosure.

FIG. 3 shows an example of a digital material according to the present disclosure.

FIG. 4 shows an example collaboration between a requestor entity and a provider entity supported by digital material collaboration capabilities of the present disclosure.

FIG. 5 shows an example of logic that a system may implement to provide digital material collaboration platforms capabilities.

FIG. 6 shows an example of a computing system that supports digital material collaboration platforms.

### DETAILED DESCRIPTION

With continuing technology advances, modern manufacturing processes have become increasingly powerful, yet complex. Composite layup processes provide capabilities to construct products with distinct and specified physical characteristics in efficient manners. Additive manufacturing (AM) technologies have the potential to transform entire industries by expanding design freedoms, reducing time-to-market, positioning production geographically closer to demand, and improving industrial sustainability. However, the complexity of properly designing and producing products through such manufacturing technologies can limit the widespread adoption and use of such technologies. With near-limitless technical flexibilities of composite layup and AM manufacturing technologies, even slight variations in the material, machines, and manufacturing process parameters used can greatly impact product generation, oftentimes resulting in manufacturing defects, imperfections, or unintended product characteristics.

As such, one prevailing challenge in the use of complex manufacturing processes is the high difficulty to manufacture a product correctly a first time through. To reach such a goal (and thus manufacture high-quality parts that completely fulfill design intent and product specifications), a part manufacturer may need to ascertain optimized process parameters for part construction of a specific additive material with a specific 3D geometry via a specific AM machine. However, such information is rarely readily available to a single entity. For instance, if an AM user buys a powder bed fusion machine to produce parts with a specific material, the AM user often receives a starter kit for process parameters to process the specific material on this purchased powder bed fusion machine. However, the starter kit is just a limited starting point and proper part construction can require trial and error tests through AM printing, post processing, and final quality analysis of the part.

Such trial testing may need to be continually performed until the optimized process parameters can be derived for the specific part geometry, the specific material, and the selected machine. Such processes can be time consuming, leading to high development costs and preventing the widespread adoption of AM technology. Similar challenges and time-consuming trial-and-error experiments may be prevalent for composite layups and other complex manufacturing technologies.

Often in such design of experiments to determine optimized processing parameters, several parts at various process conditions are 3D printed and the part quality is cost-analyzed to derive the most suitable process parameter set. To reduce manual work, loss of time, and resource consumption (including cost-intensive raw materials), finite element method (FEM) simulations of manufacturing processes can be performed. However, to define the correct simulation model for the simulation requires immense knowledge and experience. Furthermore, simulation technologies can provide inaccurate results without a complete set of material properties of the specific physical material undergoing the printing simulation and post-processing analysis, and such material specifications are oftentimes unavailable without extensive experimentation. Some database systems can store material data (at a cost), but do not provide a standardized format for consumption of the data (e.g., via simulation) nor do such databases provide any capability to collaborate with other entities to determine optimized materials, process parameters, and machines for construction of physical parts.

The disclosure herein may provide systems, methods, devices, and logic for digital material collaboration platforms. As described in greater detail below, the digital material collaboration technology of the present disclosure may support construction and use of digital materials, including through collaboration and information exchanges between various entities of a digital material collaboration platform. A digital material according to the present disclosure may refer to a digital representation of multiple aspects of a manufacturing process to produce a physical part. As such, a digital material may define (e.g., specify) a physical material (including how the material behaves during manufacturing processes), a particular machine (and any relevant aspect thereof), and specific process parameter values used to manufacture a part using the physical material. Various aspects of digital materials according to the present disclosure are described herein. Through the collaboration capabilities described herein, the digital material collaboration technology of the present disclosure may allow for the exchange of material, process, or machine information through digital material formats. Such collaboration may support an ecosystem in which manufacturing producers, material providers, machine businesses, and more can exchange manufacturing knowledge, allowing the determination of optimized process parameters for requested material specifications without undue and tedious experimentation. As examples, process parameters can be provided expressly or directly as specified parameter values in a digital material or via data models in the digital material through which FEM or other simulation tools can calculate the proper or optimal process parameters for a particular design, machine, or manufacturing process.

In some implementations, the digital material collaboration technology of the present disclosure may provide the capability for multiple entities to jointly define a digital material that encompasses an entire material value chain. In doing so, the digital material collaboration technology can support multi-entity shaping of properties of a physical material according to requirements for real-world fabrication and consumption. As such, the collaboratively constructed digital materials of the present disclosure can be used to drive and support physical manufacture of the defined material, new product designs, product life monitoring, remanufacturing, recycling, and reuse. Through collaboration and co-creation of high-quality AM processes for specific product materials and 3D designs, the digital material collaboration technology of the present disclosure can result in increased physical part quality and increase the efficiencies and speed of part manufacture processes. This can further lead to accelerated adoption of AM or other manufacturing technologies and speed up sustainable product development with new or advanced materials and corresponding manufacturing processes on an industrial scale.

These and other digital material collaboration features and benefits are described in greater detail herein.

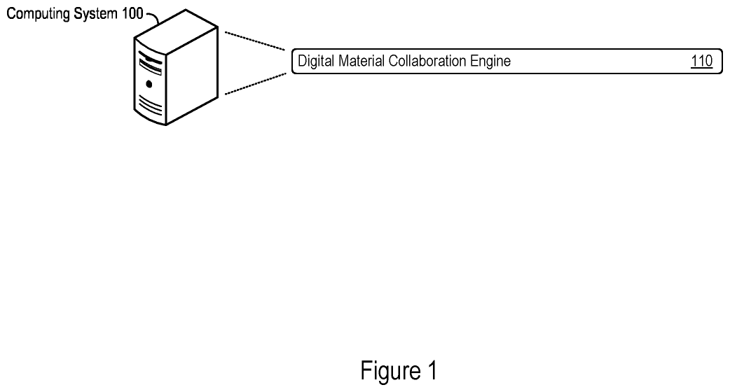

FIG. 1 shows an example of a computing system 100 that supports digital material collaboration platforms. The computing system 100 may take the form of a single or multiple computing devices such as application servers, compute nodes, desktop or laptop computers, smart phones or other mobile devices, tablet devices, embedded controllers, and more. In some examples, the computing system 100 implements or executes a digital material collaboration platform, which may take the form of any application or program that provides any of the digital material collaboration technology presented herein.

As an example implementation to support any combination of the digital material collaboration features described herein, the computing system 100 shown in FIG. 1 includes a digital material collaboration engine 110. The computing system 100 may implement the digital material collaboration engine 110 (including components thereof) in various ways, for example as hardware and programming. The programming for the digital material collaboration engine 110 may take the form of processor-executable instructions stored on a non-transitory machine-readable storage medium and the hardware for the digital material collaboration engine 110 may include a processor to execute those instructions. A processor may take the form of single processor or multi-processor systems, and in some examples, the computing system 100 implements multiple engines using the same computing system features or hardware components (e.g., a common processor or a common storage medium).

In operation, the digital material collaboration engine 110 may construct a digital material that is partially-defined based on input from a requestor entity of a digital material collaboration platform. The digital material may be for the manufacture of a physical product and may be partially-defined to include a physical material or product requirements for the physical product, but does not define process parameters of a manufacturing process to manufacture the physical product. In operation, the digital material collaboration engine 110 may also provide access to the digital material partially-defined by the requestor entity on the digital material collaboration platform, receive, from provider entities of the digital material collaboration platform, proposed versions for the digital material that specify process parameters for the manufacturing process, and connect the requestor entity with a selected provider entity of the provider entities of the digital material collaboration platform based on a particular proposed version for the digital material provided by the selected provider entity.

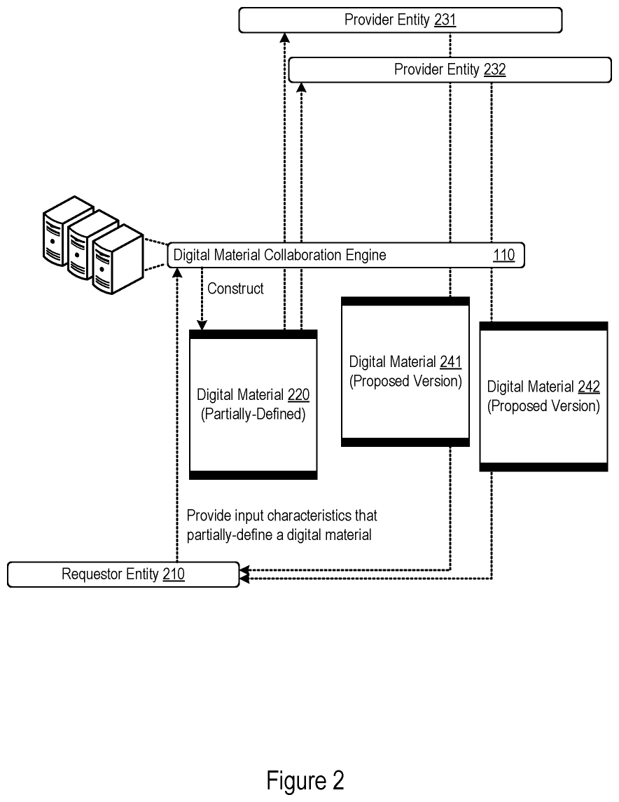

These and other digital material collaboration features according to the present disclosure are described in greater detail next. In some implementations, the digital material collaboration engine 110 may implement or otherwise provide various capabilities of a digital material collaboration platform allowing various entities to collaborate together to request, propose, evaluate, consume, develop, or otherwise use digital materials. The digital material collaboration engine 110 may support collaboration in the form of exchanged versions of digital materials that specify requested or proposed material requirements, proposing process parameters and features between the various entities. Through such digital material exchanges, a digital material collaboration platform can support the co-creation of digital materials with precise material and product specifications for a specific 3D design with optimized process parameters. Example features of digital material exchanges according to the present disclosure are presented next with reference to FIG. 2.

FIG. 2 shows an example generation and exchange of various versions of digital materials according to the present disclosure. In the example of FIG. 2, the digital material collaboration engine 110 may provide any number of collaboration capabilities between various entities. In some implementations, the digital material collaboration engine 110 may implement a digital material collaboration platform, which may take the form of a software application (e.g., portal) through which users can access, provide, design, co-create, and otherwise collaborate together for the generation of digital materials. Any number of entities may benefit from a digital material collaboration platform, including any number of roles, users, or others involved in any point of material flow/material value chain.

As examples, supplier-side roles such as material suppliers, material developers, material testing labs, manufacturing equipment providers, and more may utilize the digital material collaboration platform to share expertise and propose material data (e.g., in the form of material data models) and process parameters for various product designs. Various roles and actors across an entire PLM spectrum may similarly utilize a digital material collaboration platform, such as product and technology innovators, design engineers, materials processors, physical part manufacturers, end users, and more. Any such entities may utilize a digital material collaboration platform to co-create digital materials and share information based on specific domains of expertise.

As one example entity, FIG. 2 includes a requestor entity 210. The requestor entity 210 may be a user or account of the digital material collaboration platform, and the digital material collaboration engine 110 may construct a digital material based on a request submitted by the requestor entity 210. The digital material constructed by the digital material collaboration engine 110 for the requestor entity 210 may be partially-defined in that only some, but not all, of the material or process parameter data of the partially-defined digital material is specified. For example, the digital material collaboration engine 110 may construct a partially-defined digital material for manufacture of a physical product that is partially-defined to include a physical material or product requirements for the physical product, but does not define process parameters of a manufacturing process to manufacture the physical product. As another example, the digital material collaboration engine 110 may construct a partially-defined digital material that defines any number of material, process, or machine requirements, but does not specify some (e.g., does not specify any) parameter values to manufacture the physical product.

In that regard, the partially-defined digital material constructed for the requestor entity 210 can flexibly specify any number of requirements for a physical product, defined in the ontology (further described herein) of digital materials supported by the digital material collaboration platform. In the example of FIG. 2, the digital material collaboration engine 110 constructs the partially-defined digital material 220 based on input from the requestor entity 210, which may only define some, but not all, aspects, parameters, requirements, or values for a digital material according to the present disclosure. As noted herein, the partially-defined digital material 220 may specify requirements for the digital material, whether for a material, machine, or process used to manufacture a physical product, allowing further collaboration with other entities for options and proposals to meet the specified requirements. Some example portions that may comprise a partially-defined digital material are described herein.

As one example portion, a partially-defined digital material 220 constructed by the digital material collaboration engine 110 for the requestor entity 210 may comprise a part geometry of a physical product (e.g., a CAD file) or a limited subset of the geometrical characteristics of the physical geometry (e.g., dimensions, a general shape, surface topology, etc.). As another example portion, the partially-defined digital material may specify any number of product requirements for the physical product, such as target properties for the physical product to exhibit (e.g., yield strength, fatigue properties), manufacturing requirements, or any other suitable constraint for the physical product or manufacture thereof. While some example portions of partially-defined digital materials are described herein, the digital material collaboration engine 110 may construct a partially-defined digital material for a requestor entity 210 according to any input specified by the requestor entity 210, which may specify any combination of material, process, or machine requirements for manufacture of a physical product.

Partially-defined digital materials constructed based on input from requestor entities can allow for collaboration and information exchange with other entities of a digital material collaboration platform. To support such exchanges, the digital material collaboration engine 110 may provide other entities of a digital material collaboration platform with access to partially-defined digital materials. In FIG. 2, the digital material collaboration engine 110 provides access to the digital material 220 partially-defined by the requestor entity 210 on the digital material collaboration platform, for example by publishing the partially-defined digital material 220 on the digital material collaboration platform. Publishing may be performed by the digital material collaboration engine 110 in any suitable manner such that other entities of a digital material collaboration platform can access partially-defined digital materials. As one example, the digital material collaboration engine 110 may provide search capabilities for entities to perform keyword searches or other forms of searches on the digital material collaboration platform to locate and access partially-defined digital materials such as the partially-defined digital material 220. As another example, the digital material collaboration engine 110 may post partially-defined digital materials in a particular online location of the digital material collaboration platform, such as a dedicated channel or web page section. Any other suitable forms of access digital material access are contemplated herein.

An example of entities that may access partially-defined digital materials are provider entities, such as the provider entities 231 and 232 shown in FIG. 2. A provider entity may refer to any account, user, or other entity that exchanges, provides, or proposes information for digital materials of a digital material collaboration platform. Provider entities may thus include any entity with knowledge of manufacturing processes, materials, and machines. Example provider entities may include material developers and suppliers (e.g., of powder or other AM materials), providers of manufacturing machines and equipment, process developers, etc. The provider entities may possess manufacturing knowledge for specific materials and material types (e.g., as acquired via development of the material itself), specific machines (e.g., as builders and designers of AM machinery or other equipment, process developers, and even other product manufacturers who may possess manufacturing knowledge of materials, machines, and process parameters through experience.

The provider entities of a digital material collaboration platform may propose any number of characteristics, attributes, parameter values, or other aspects of a digital material definition in order to fulfill the requirements set forth in a partially-defined digital material constructed for a requestor entity. In doing so, provider entities may co-create a digital material definition with a requestor entity, providing various offerings, proposals, or definitions in order to strive to meet the product requirements of a requestor entity as set forth in a partially-defined digital material. The digital material collaboration engine 110 may support information exchanges by providing access of partially-defined digital materials to provider entities and receiving, from the provider entities of the digital material collaboration platform, proposed versions for the digital material. The proposed versions of the digital materials provided by the provider entities may include any number of defined process parameter values, material values, or other characteristics of a digital material to satisfy requirements of a partially-defined digital material.

In the example of FIG. 2, the provider entities 231 and 232 each generate a proposed version of the partially-defined digital material 220, shown in FIG. 2 respectively as the digital material 241 and the digital material 242. The digital materials 241 and 242 provided by the provider entities 231 and 232 as proposed versions may include, as examples, defined process parameter values to meet product requirements set forth in the partially-defined digital material 220 and/or suggested materials (with corresponding material characteristics) to use to manufacture the physical product. As another example, a digital material may specify or include data models for physical materials used in manufacturing processes. Such data models may provide advanced and complex material properties aside from basic properties of a material (e.g., as specified in a data sheet). The data models may, for example, model material behavior in manufacturing processes, and may thus be suited for use in CAE, CAD, or other simulations for products. Provider entities (such as material suppliers or developers) may, for example, provide data models as part of proposed version of digital materials in information exchanges on the digital material collaboration platform.

The degree to which the provider entities 231 and 232 define the digital materials 241 and 242 with discrete material, process parameter, and machine parameter values may vary, allowing provider entities to flexibly specify (and thus propose) as much or as little information as desired during collaboration and information exchanges with requestor entities. In some implementations (and as discussed in greater detail herein), digital materials may comprise public and private sections. The proposed versions of the digital material 241 and 242 defined by the provider entities 231 and 232 may include material, process, or machine features or properties specified in a public section for review by the requestor entity 231, but the actual material and process parameter values may be hidden in the private sections.

The digital material collaboration engine 110 may receive proposed versions of digital materials provided by provider entities that support review and consideration by the requestor entity. In that regard, the proposed version of digital materials 241 and 242 from the provider entities 231 and 232 may, in some sense, serve as proposals to the requestor entity for particular materials, processes, or parameters that can be used to construct a physical product with the requirements specified in the partially-defined digital material 220. The proposed versions of the digital material 241 and 242 may comprise provider-specific data specified by the provider entities 231 and 232 in both the private and the public sections of the proposed versions of the digital material 241 and 242, and the requestor entity 231 may review the proposed versions via access to the public portions but may be limited in access to some or all of the data stored in the private sections.

In some implementations, the digital material collaboration engine 110 may support multiple rounds of exchanges between the requestor entity 210 and provider entities 231 and 242 for a digital material. For instance, the digital material collaboration engine 110 may receive a counter-proposed version of the digital material from the requestor entity 210, which may specify additional or adjusted requirements for a product, additional material requirements, excluded processes, machines, or equipment, or any other additional or alternative requirement, property, or parameter for the digital material. This counter-proposed version of the digital material may be obtained by altering the proposed versions of the digital material 241 and/or 242 provided by the requestor entities 231 and 232. The digital material collaboration engine 110 may then provide the counter-proposed version of the digital material to some or all of the provider entities.

Through such exchanges via varying proposed versions for a digital material, the digital material collaboration engine 110 may support information exchange between various entities of a digital material collaboration platform. Such collaborations supported by the digital material collaboration technology of the present disclosure may be mutually beneficial to participating entities, as information exchanges and resulting digital material constructions can be derived from the material life cycle (and thus involving material, process, and machine providers and was as product manufacturers). As another benefit, such open collaboration as provided by the present disclosure may accelerate material developments required for consumption, as joint exchanges of know-how and expertise may reduce many of the time-consuming experimental validation processes to determine optimal process parameters for specific materials.

Consequent to the digital material version exchange(s) between the requestor entity 210 and provider entities 231 and 232, the digital material collaboration engine 110 may receive a selection of a particular digital material proposal, which may also be understood or implemented as selection of a selected provider entity. To illustrate, the requester entity 210 may accept the proposed version of the digital material 241 as provided by provider entity 231, as the particular material, process, or machines specified in the proposed version of the digital material 241 align more closely with the requirements sent forth in the partially-defined digital material 220 than other proposed versions. In this case, the digital material collaboration engine 110 may connect the requestor entity 210 with the selected provider entity of the provider entities of the digital material collaboration platform (in this case the provider entity 231), doing so based on the particular proposed version for the digital material 241 provided by the selected provider entity.

Connecting the requestor entity 210 to a selected provider entity may be performed in various ways. For instance, the digital material collaboration engine 110 may open a communication channel between the requestor entity 210 and the provider entity 231, e.g., by providing email addresses, creating communication lines, starting a chat, or in any other suitable manner. As another example, the digital material collaboration engine 110 may “unlock” the proposed version of the digital material 241 to access any private sections of the digital material. As such, the digital material collaboration engine 110 may limit access to such private sections of a digital material to protect confidential or secret data of providers, only unlocking such private sections when a requestor entity selects the particular provider entity (and accordingly its specific materials and process parameter values). Accordingly, the digital material collaboration engine 110 may connect the requestor entity 210 with a selected provider entity by providing access, to the requestor entity 231, to the private section of the particular proposed version for the digital material provided by the selected provider entity.

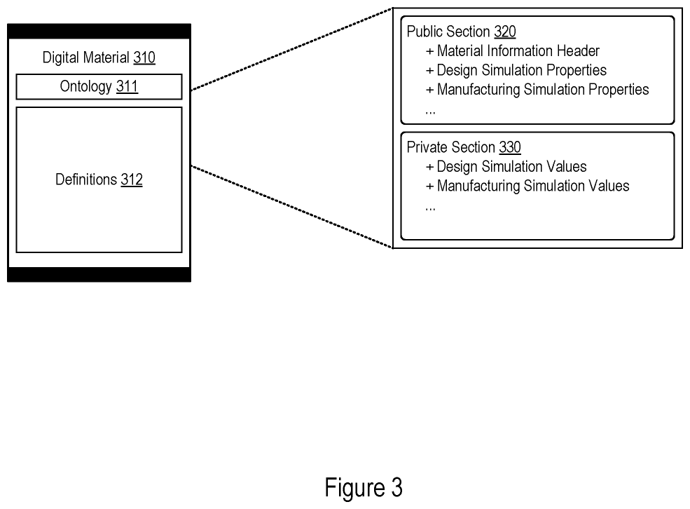

In any such manner as described herein, a digital material collaboration platform (e.g., via digital material collaboration engine 110) may provide capabilities to exchange knowledge of materials, process parameters, and machines as encapsulated through digital materials. As such, the digital materials of the present disclosure may provide an efficient and elegant manner in which to represent advanced material data, which can include increased information and flexibility as compared to conventional material data sheets. In that regard, the digital materials of the present disclosure can store any type of data as relevant to the manufacture of a particular physical product, including material definitions, process parameters, design geometry, machine specifications, and the like. As noted herein, digital materials of the present disclosure may comprise public and private sections. Example features of a digital material are described in further detail next with reference to FIG. 3.

FIG. 3 shows an example of a digital material 310 according to the present disclosure. The digital material collaboration engine 110 may construct or modify the digital material 310 in support of the digital material collaboration features of the present disclosure. In some implementations, the digital material collaboration engine 110 may construct the digital material 310 as a knowledge graph that includes an ontology 311 and definitions 312. The ontology 311 of the digital material 310 may define the various properties, parameters, or other objects that can be specified in the digital material 310 (and their relationships to one another) and the definitions 310 can provide specific data values for the defined properties, parameters, and objects of the ontology 311.

Digital materials of the present disclosure can support definition of any aspect of a material, process, or machine relevant to the manufacture of a physical product. In some implementations, the ontology 311 of a digital material 310 may include types or classes to categorize different properties and parameters. As example types of classes supported by the digital material 310, the ontology 311 may define classes including material development, manufacturing processes, manufacturing control, applicable interfaces to CAD or CAE applications (e.g., simulation technology), material recycling, experimental validation, virtual validation, and many more. Each class may define specific properties in the ontology 311 and the definitions 312 of the digital material 310 may specify specific values for any of the defined class properties. Example properties and values that the digital material 310 may specify include (without limitation), design simulation properties and values, manufacturing simulation properties and values, manufacturing process properties and values (e.g., process parameters), heat treatment properties and values, visualization properties and values, sustainability properties and values, and more.

Note that the digital material 310 may support definition of simulation properties and values (whether for a design, product manufacture, or both). By doing so, the digital material collaboration engine 110 may support the direct consumption of the digital material 310 by simulation applications. The digital material 310 may provide a standardized format by which to store and represent data that can be used by disparate CAE and CAD applications for processing digital material data, including in simulations. Thus, the digital material 310 may set a consistent format by which to simulate material and process data, allowing for broader adoption of manufacturing technologies like AM and composite layup. The digital material collaboration engine 110 may thus construct the digital material 310 in a format supported for direct consumption by a manufacturing simulation of the digital material 310. The digital material may also be supported for direct consumption in other types of simulations as well, such as design simulations, CAD simulations, simulations accessing data from enterprise databases, and the like.

As also shown in FIG. 3, the digital material collaboration engine 110 may construct the digital material 310 to include public and private sections, shown as the public section 320 and private section 330 in FIG. 3. The digital material 310 is flexible as the ontology 311 (or any other data structure format of the digital material 310) can designate any property or value as part of the public section 320 or the private section 330. Access to the digital material information specified in the private section 330 may be limited and controlled to prevent unauthorized access. The digital material collaboration engine 110 may limit access to the private section 330 of the digital material 310 in any suitable manner, e.g., encryption. In some circumstances, the digital material collaboration engine 110 may “unlock” the private section 330 of the digital material 310 for access by specific entities of a digital material collaboration platform, such as a for a requestor entity connected with a provider entity for a particular proposed version of a digital material.

Through private sections of a digital material, the digital material collaboration engine 110 may protect or limit access to confidential information of specific entities of the digital material collaboration platform. By doing so, the digital material collaboration engine 110 may spur increased participation in the digital material collaboration platform so that material and process developers, machine suppliers, and others may control when and how their manufacturing knowledge is distributed and shared. The digital material collaboration engine 110 may thus construct digital materials to comprise a public section and a private section, wherein the private section has increased access restrictions as compared to the public section of the digital material.

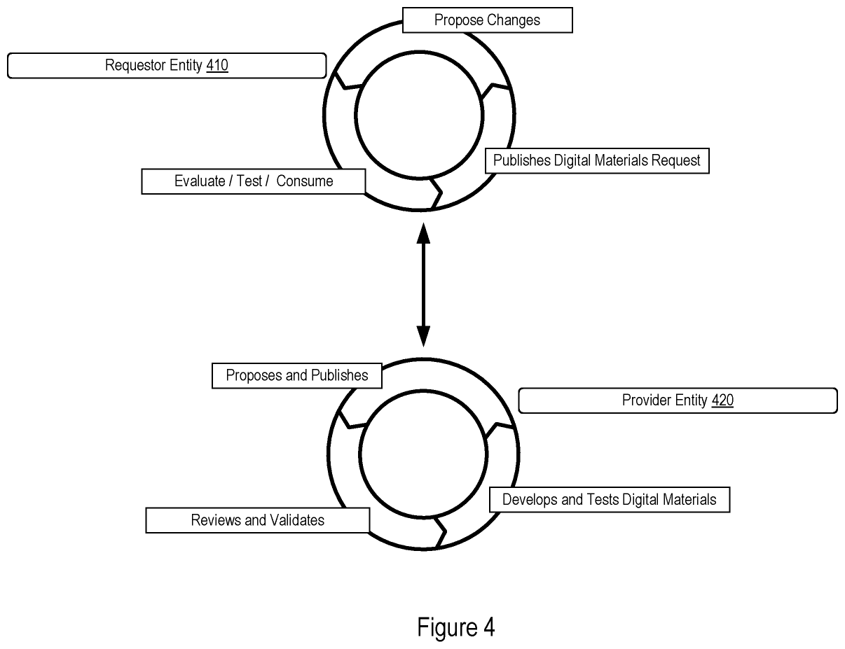

FIG. 4 shows an example collaboration between a requestor entity 410 and a provider entity 420 supported by digital material collaboration capabilities of the present disclosure. Digital material collaboration platforms may support any of the exchanges described herein between various entities of the platform. For example, in FIG. 4, the requestor entity 410 may support digital material exchanges by publishing digital material requests (e.g., in the form of partially-defined digital materials), proposing changes to proposed digital material provided in response to the request, and evaluating, testing, or consuming proposed digital material versions from selected provider entities.

In FIG. 4, the provider entity 420 may also utilize collaboration capabilities provided by the digital material collaboration platform. As examples, the provider entity 420 may develop and test digital materials and thus acquire expertise and knowledge for materials, manufacturing processes, manufacturing machinery, or combinations thereof. The provider entity 420 may identify digital material requests and propose (e.g., via publishing) responses to the request in the form of proposed versions of digital materials. The provider entity 420 may also review and validate counter-proposed versions in exchanges with requestor entities. Through collaborations between entities of a digital material collaboration platform, such as shown in FIG. 4, increased information sharing and adoption of complex manufacturing technologies can be achieved.

In some implementations, the digital material collaboration platform described herein can serve as a marketplace for entities to provide, exchange, and acquire technical knowledge from various sources. Rating systems can be implemented for the digital material collaboration platform to ensure the quality of exchanged information and validate the legitimacy of provider entities and their provided information. The entities that can participate in such a marketplace can easily span the entire material value chain, from material developers, suppliers, product and technology innovators, machine builders, process developers, and many more. In such mutual and collaborative efforts, the digital material of the present disclosure may provide a technical mechanism to ensure consistent, secure, and flexible information exchanges can occur.

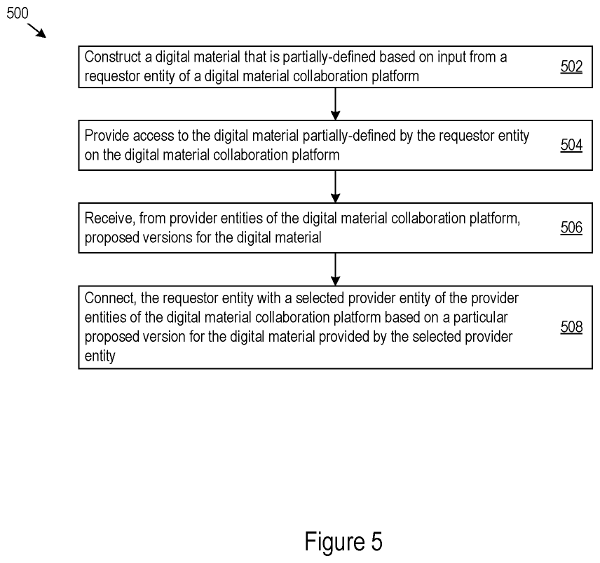

FIG. 5 shows an example of logic 500 that a system may implement to support digital material collaboration platforms. For example, the computing system 100 may implement the logic 500 as hardware, executable instructions stored on a machine-readable medium, or as a combination of both. The computing system 100 may implement the logic 500 via the digital material collaboration engine 110, through which the computing system 100 may perform or execute the logic 500 as a method to support any number of digital material collaboration capabilities. The following description of the logic 500 is provided using the digital material collaboration engine 110 as an example. However, various other implementation options by systems are possible.

In implementing the logic 500, the digital material collaboration engine 110 may construct a digital material that is partially-defined based on input from a requestor entity of a digital material collaboration platform (502) and provide access to the digital material partially-defined by the requestor entity on the digital material collaboration platform (504), doing so in any of the ways described herein. In implementing the logic 500, the digital material collaboration engine 110 may further receive, from provider entities of the digital material collaboration platform, proposed versions for the digital material that specify process parameters for the manufacturing process (506), and connect the requestor entity with a selected provider entity of the provider entities of the digital material collaboration platform based on a particular proposed version for the digital material provided by the selected provider entity (508).

The logic 500 shown in FIG. 5 provides but one example by which a computing system 100 may support digital material collaboration platforms. Additional or alternative steps in the logic 500 are contemplated herein, including according to any features described herein for the digital material collaboration engine 110.

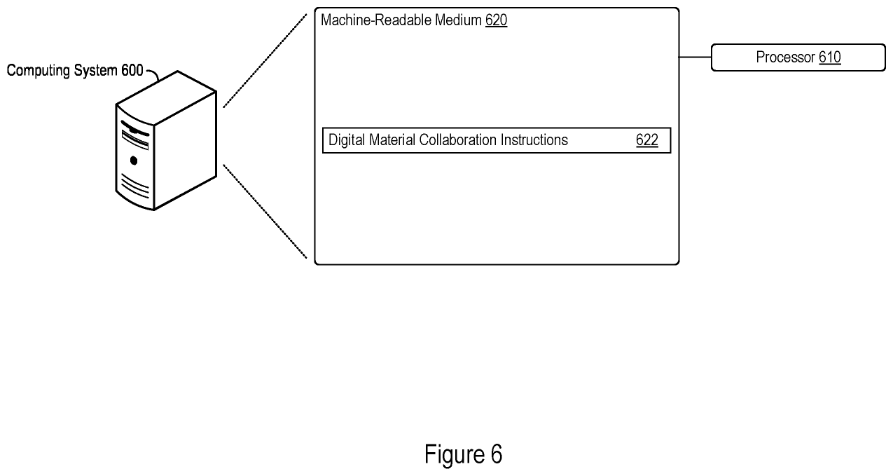

FIG. 6 shows an example of a computing system 600 that supports digital material collaboration platforms. The computing system 600 may include a processor 610, which may take the form of a single or multiple processors. The processor(s) 610 may include a central processing unit (CPU), microprocessor, or any hardware device suitable for executing instructions stored on a machine-readable medium. The computing system 600 may include a machine-readable medium 620. The machine-readable medium 620 may take the form of any non-transitory electronic, magnetic, optical, or other physical storage device that stores executable instructions, such as the digital material collaboration instructions 622 shown in FIG. 6. As such, the machine-readable medium 620 may be, for example, Random Access Memory (RAM) such as a dynamic RAM (DRAM), flash memory, spin-transfer torque memory, an Electrically-Erasable Programmable Read-Only Memory (EEPROM), a storage drive, an optical disk, and the like.

The computing system 600 may execute instructions stored on the machine-readable medium 620 through the processor 610. Executing the instructions (e.g., the digital material collaboration instructions 622) may cause the system computing 600 to perform any of the digital material collaboration features described herein, including according to any of the features with respect to the digital material collaboration engine 110.

For example, execution of the digital material collaboration instructions 622 by the processor 610 may cause the computing system 600 to construct a digital material that is partially-defined based on input from a requestor entity of a digital material collaboration platform, doing so in any of the ways described herein. Execution of the digital material collaboration instructions 622 may further cause the computing system 600 to provide access to the digital material partially-defined by the requestor entity on the digital material collaboration platform, receive, from provider entities of the digital material collaboration platform, proposed versions for the digital material that specify process parameters for the manufacturing process, and connect the requestor entity with a selected provider entity of the provider entities of the digital material collaboration platform based on a particular proposed version for the digital material provided by the selected provider entity

Any additional or alternative features of the present disclosure may be implemented via the digital material collaboration instructions 622.

The systems, methods, devices, and logic described above, including the digital material collaboration engine 110, may be implemented in many different ways in many different combinations of hardware, logic, circuitry, and executable instructions stored on a machine-readable medium. For example, the digital material collaboration engine 110 may include circuitry in a controller, a microprocessor, or an application specific integrated circuit (ASIC), or may be implemented with discrete logic or components, or a combination of other types of analog or digital circuitry, combined on a single integrated circuit or distributed among multiple integrated circuits. A product, such as a computer program product, may include a storage medium and machine-readable instructions stored on the medium, which when executed in an endpoint, computer system, or other device, cause the device to perform operations according to any of the description above, including according to any features of the digital material collaboration engine 110.

The processing capability of the systems, devices, and engines described herein, including the digital material collaboration engine 110, may be distributed among multiple system components, such as among multiple processors and memories, optionally including multiple distributed processing systems or cloud/network elements. Parameters, databases, and other data structures may be separately stored and managed, may be incorporated into a single memory or database, may be logically and physically organized in many different ways, and may be implemented in many ways, including data structures such as linked lists, hash tables, or implicit storage mechanisms. Programs may be parts (e.g., subroutines) of a single program, separate programs, distributed across several memories and processors, or implemented in many different ways, such as in a library (e.g., a shared library).

While various examples have been described above, many more implementations are possible.

1. A method comprising:
by a computing system:
constructing a digital material that is partially-defined based on input from a requestor entity of a digital material collaboration platform, wherein the digital material is for manufacture of a physical product and is partially-defined to include a physical material or product requirements for the physical product, but does not define process parameters of a manufacturing process to manufacture the physical product;
providing access to the digital material partially-defined by the requestor entity on the digital material collaboration platform;
receiving, from provider entities of the digital material collaboration platform, proposed versions for the digital material that specify process parameters for the manufacturing process; and
connecting the requestor entity with a selected provider entity of the provider entities of the digital material collaboration platform based on a particular proposed version for the digital material provided by the selected provider entity.

2. The method of claim 1, comprising constructing the digital material to comprise a public section and a private section, wherein the private section has increased access restrictions as compared to the public section of the digital material.

3. The method of claim 2, wherein the proposed versions comprise provider-specific data specified by the provider entities in both the private and the public sections of the proposed versions of the digital material.

4. The method of claim 3, further comprising allowing the requestor entity to review the public portions but not the private portions of the proposed versions of the digital material.

5. The method of claim 3, wherein connecting the requestor entity with the selected provider entity comprises providing access, to the requestor entity, to the private section of the particular proposed version for the digital material provided by the selected provider entity.

6. The method of claim 1, comprising constructing the digital material in a format supported for direct consumption by a manufacturing simulation of the digital material.

7. The method of claim 1, comprising constructing the digital material as a knowledge graph.

8. A system comprising:
a digital material collaboration engine configured to:
construct a digital material that is partially-defined based on input from a requestor entity of a digital material collaboration platform, wherein the digital material is for manufacture of a physical product and is partially-defined to include a physical material or product requirements for the physical product, but does not define process parameters of a manufacturing process to manufacture the physical product;
provide access to the digital material partially-defined by the requestor entity on the digital material collaboration platform;
receive, from provider entities of the digital material collaboration platform, proposed versions for the digital material that specify process parameters for the manufacturing process; and
connect the requestor entity with a selected provider entity of the provider entities of the digital material collaboration platform based on a particular proposed version for the digital material provided by the selected provider entity.

9. The system of claim 8, wherein the digital material collaboration engine is configured to construct the digital material to comprise a public section and a private section, wherein the private section has increased access restrictions as compared to the public section of the digital material.

10. The system of claim 9, wherein the proposed versions comprise provider-specific data specified by the provider entities in both the private and the public sections of the proposed versions of the digital material.

11. The system of claim 10, wherein the digital material collaboration engine is further configured to allow the requestor entity to review the public portions but not the private portions of the proposed versions of the digital material.

12. The system of claim 10, wherein the digital material collaboration engine is configured to connect the requestor entity with the selected provider entity by providing access, to the requestor entity, to the private section of the particular proposed version for the digital material provided by the selected provider entity.

13. The system of claim 8, wherein the digital material collaboration engine is configured to construct the digital material in a format supported for direct consumption by a manufacturing simulation of the digital material.

14. The system of claim 8, wherein the digital material collaboration engine is configured to construct the digital material as a knowledge graph.

15. A non-transitory machine-readable medium comprising instructions that, when executed by a processor, cause a computing system to:
construct a digital material that is partially-defined based on input from a requestor entity of a digital material collaboration platform, wherein the digital material is for manufacture of a physical product and is partially-defined to include a physical material or product requirements for the physical product, but does not define process parameters of a manufacturing process to manufacture the physical product;
provide access to the digital material partially-defined by the requestor entity on the digital material collaboration platform;
receive, from provider entities of the digital material collaboration platform, proposed versions for the digital material that specify process parameters for the manufacturing process; and
connect the requestor entity with a selected provider entity of the provider entities of the digital material collaboration platform based on a particular proposed version for the digital material provided by the selected provider entity.

16. The non-transitory machine-readable medium of claim 15, wherein the instructions cause the computing system to construct the digital material to comprise a public section and a private section, wherein the private section has increased access restrictions as compared to the public section of the digital material.

17. The non-transitory machine-readable medium of claim 16, wherein the proposed versions comprise provider-specific data specified by the provider entities in both the private and the public sections of the proposed versions of the digital material.

18. The non-transitory machine-readable medium of claim 17, wherein the instructions further cause the computing system to allow the requestor entity to review the public portions but not the private portions of the proposed versions of the digital material.

19. The non-transitory machine-readable medium of claim 17, wherein the instructions cause the computing system to connect the requestor entity with the selected provider entity by providing access, to the requestor entity, to the private section of the particular proposed version for the digital material provided by the selected provider entity.

20. The non-transitory machine-readable medium of claim 15, wherein the instructions cause the computing system to construct the digital material in a format supported for direct consumption by a manufacturing simulation of the digital material.
